(19) United States
(12) Patent Application Publication
(10) Pub. No.: US 2012/0186648 A1
(43) Pub. Date: Jul. 26, 2012

(54) COAXIAL MOLECULAR STACK FOR TRANSFERRING PHOTOCURRENT GENERATION

(76) Inventors: Ling Zang, Salt Lake City, UT (US); Yanke Che, Salt Lake City, UT (US)

(21) Appl. No.: 13/387,162

(22) PCT Filed: Aug. 9, 2010
(86) PCT No.: PCT/US10/44927

§ 371 Date: Apr. 9, 2012

(30) Foreign Application Priority Data
Aug. 7, 2009 (US) 61232077

(51) Int. Cl. H01L 51/46; H01L 31/0224; C07D 471/16; H01L 51/42; C07D 471/06

(52) U.S. Cl. 136/256; 438/93; 546/37; 546/29; 546/26; 546/28; 136/263; 136/251; 257/E51.012

(57) ABSTRACT

A photovoltaic device (10) having a coaxial molecular stack (12) for transferring photocurrent is disclosed. The device (10) comprises a plurality of coaxial molecular stacks (12) located between and oriented substantially perpendicular to first (14) and second (16) electrodes to provide charge transport of photocurrent through each coaxial molecular stack (12) in the photovoltaic device (10). Each coaxial molecular stack (12) comprises a plurality of π-conjugated planar supramolecules (18) stackable through columnar self assembly to form the coaxial molecular stack (12). Each supramolecule (18) is comprised of a π-conjugated hub (20) covalently appended to multiple copies of an electron acceptor spoke (22) to form an outer n-channel with a coaxial inner p-channel.

### RELATED APPLICATIONS

This application claims the benefit of U.S. Provisional Application No. 61/232,077, filed Aug. 7, 2009 which is incorporated herein by reference.

### BACKGROUND

Organic based solar cells have distinct advantages over their inorganic counterparts, such as low cost of fabrication, ease for large area processing, and compatibility with flexible and light weight plastic substrates, and thus have attracted enormous amount of research interest and effort in the past decades. However, organic solar cells typically suffer from low efficiency of light conversion (usually less than 5%) that inhibits their use in practical applications at the present.

The efficiency of organic solar cells is largely determined by four basic, consequential processes: exciton diffusion; charge generation via electron transfer; charge separation and transport. Although the recent development of bulk-heterojunction materials (e.g., polymer/C60) has shown promise in improving the first two processes by creating charge separation via photoinduced intra- and inter-molecular electron transfer, the poor organization and/or phase segregation of the bulk-mixed materials still limit the charge transport.

### SUMMARY

Therefore, the inventors have developed a photovoltaic device having a coaxial molecular stack for transferring photocurrent which improves upon existing technology. The device can include a plurality of coaxial molecular stacks located between and oriented substantially perpendicular to a first electrode and a second electrode. In this arrangement, the plurality of stacks can provide charge transport of photocurrent through each coaxial molecular stack in the photovoltaic device. More particularly, each coaxial molecular stack can comprise a plurality of π-conjugated planar supramolecules which are stackable through columnar self assembly to form the coaxial molecular stack. Further, each supramolecule is comprised of a π-conjugated hub covalently appended to multiple copies of an electron acceptor spoke to form an outer n-channel with a coaxial inner p-channel.

A method of forming a photovoltaic device having a coaxial molecular stack for transferring photocurrent can include coating a first electrode with a substantially continuous film formed of a plurality of coaxial molecular stacks. A second electrode can be coupled with the film such that a plane of the second electrode is substantially parallel with the plane of the first electrode. Distance between opposing electrodes can be kept substantially constant in order to prevent or reduce preferential shorting across the smallest gap distance.

### BRIEF DESCRIPTION OF THE DRAWINGS

Features and advantages of the invention will be apparent from the detailed description which follows, taken in conjunction with the accompanying drawings, which together illustrate, by way of example, features of the invention; and, wherein:

FIG. 1 is an illustration of coaxial stacking of disc-shaped molecules located between and oriented perpendicular with a first and second electrode in accordance with an embodiment.

FIG. 2 illustrates a structure and synthesis of co-planar conjugate PTCDI-AEM supramolecules in accordance with an embodiment.

FIG. 3 illustrates an example of a concentric macrocycle architecture prepared by the repetitive cyclooligomerization of appropriate polyalkynyl precursors in accordance with an embodiment.

FIG. 4 illustrates a plot showing emission quenching of a PTCDI film over visible wavelengths.

FIG. 5 illustrates the formation of a homeotropic phase of a hexacycle AEM film formed through heating and cooling in accordance with an embodiment.

FIG. 6 illustrates a hub and spoke supramolecule of PTCDI and HBC in accordance with an embodiment.

FIG. 7 illustrates a hub and spoke supramolecule of PTCDI and AEM in accordance with an embodiment.

FIG. 8 illustrates a generic model of disc-shaped macrocyclic molecules governed by cofacial intermolecular interactions during stacking alignment in accordance with an embodiment of the present invention.

Reference will now be made to the exemplary embodiments illustrated, and specific language will be used herein to describe the same. It will nevertheless be understood that no limitation of the scope of the invention is thereby intended.

### DETAILED DESCRIPTION OF EXAMPLE EMBODIMENTS

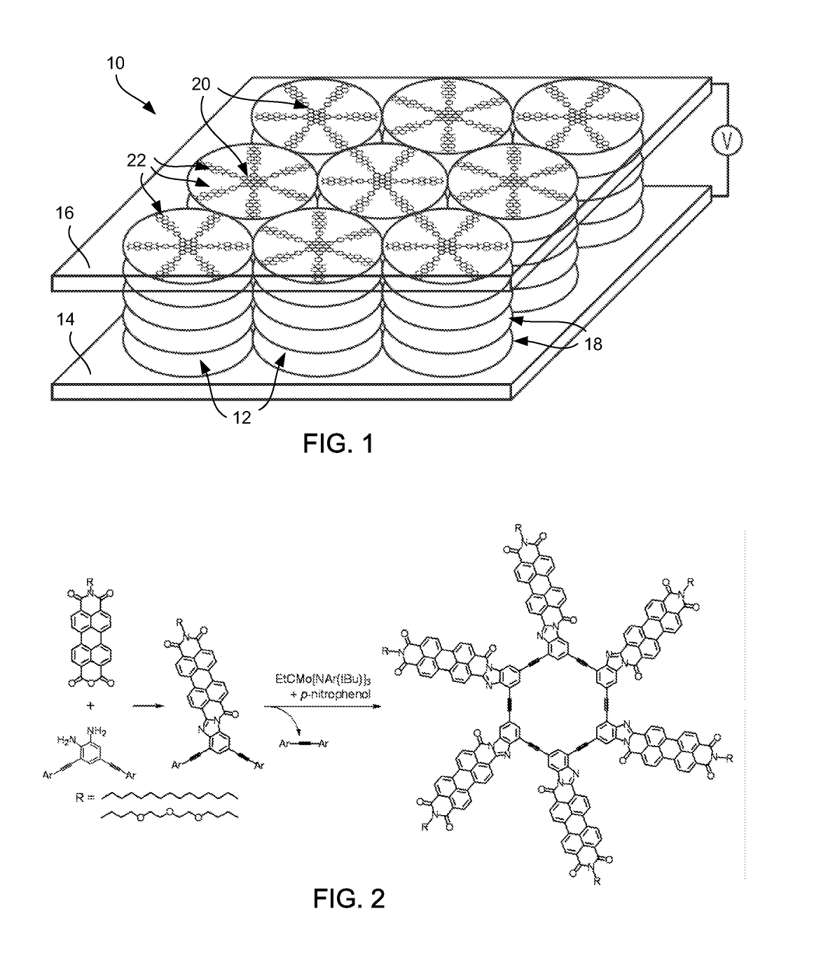

A new type of homeotropic thin film structure is disclosed that includes highly organized arrays of coaxial columns (as shown in FIG. 1) for use in a photovoltaic device for photocurrent generation. The organized arrays of coaxial columns enable highly efficient charge transport along the columnar π-π stacking via extended intermolecular π-electron delocalization.

More specifically, the photovoltaic device 10 can include a plurality of coaxial molecular stacks 12 located between and oriented substantially perpendicular to a first electrode 14 and a second electrode 16. In this arrangement, the plurality of stacks 12 can provide charge transport of photocurrent through each coaxial molecular stack 12 in the photovoltaic device 10. More particularly, each coaxial molecular stack 12 can comprise a plurality of π-conjugated planar supramolecules 18 which are stackable through columnar self assembly to form the coaxial molecular stack 12. Further, each supramolecule 18 is comprised of a π-conjugated hub 20 covalently appended to multiple copies of an electron acceptor spoke 22 to form an outer n-channel with a coaxial inner p-channel.

The π-conjugated hub can be formed of a group that planar and allows for function as a p-type material. The π-conjugated hub can be formed of at least one of arylene ethynylene macrocycle (AEM), hexabenzocoronene (HBC), porphyrins, thiophene macrocycles, and toroidal graphenes. In one aspect, the π-conjugated hub can be formed of at least one of arylene ethynylene macrocycle (AEM) and hexabenzocoronene (HBC). In another alternative aspect, the π-conjugated hub is formed of hexabenzocoronene (HBC). In one aspect, cyclic hubs can be formed of a plurality of planar sub-units which are either directly linked together or linked by linking groups. Non-limiting examples of planar sub-units can include carbazoles, benzenes, thiophenes, phenylene vinylene, porphyrins, phthalocyanines, perylene, pyrenes, graphenes, and combinations thereof. Depending on the groups, these sub-units can form cyclic tetramer, pentamers, hexamers, and the like. These sub-units can optionally be grouped into oligomers (dimers, trimers, tetramers, pentamers, hexamers, etc) such that cyclization results in multiple repeating oligomer units. Linking groups can be used to create the macrocyclic structure and maintain planar configuration. The linking groups can be triple or double bonds directly between sub-units and can optionally include planar linking groups such as phenylene, biphenylene, amine, thiol, carbonyl, and the like.

In some embodiments, the central hub portion of the supramolecule can be a cyclic molecule. Non-limiting examples of such cyclic hubs can include AEM. In one specific aspect, the supramolecule comprises PTCDI units bonded to a carbazole tetracycle, although a PTCDI substituted hexacycle (e.g. six molecular units covalently bonded in a ring) can also be used. Generally, the π-conjugated hub has a lower electron affinity than the electron acceptor spokes to provide an efficient intramolecular charge transfer upon photoexcitation.

The supramolecules can be formed using any suitable technique. Generally, the hub can be formed of a suitable precursor. These planar supramolecule hubs can be produced in one step from simple precursors. One approach relies on reversible alkyne metathesis to generate predominately a single cyclooligomeric product. Specific steps to produce these types of cyclic materials can be found, for example, in Zhang, W. & Moore, J. S. Arylene Ethynylene Macrocycles Prepared by Precipitation-Driven Alkyne Metathesis, J. Am. Chem. Soc 126, 12796 (2004); Zhang, W. & Moore, J. S. Reaction Pathways Leading to Arylene Ethynylene Macrocycles via Alkyne Metathesis, Journal of the American Chemical Society 127, 11863-11870 (2005); and Zhang, W. & Moore, J. S. Shape-persistent macrocycles: structures and synthetic approaches from arylene and ethynylene building blocks (a review), Angew. Chem., Int. Ed. 45, 4416-4439 (2006), each of which is incorporated herein by reference. In one specific example, the supramolecule can be formed through repetitive cyclooligomerization of polyalkynyl precursors as described in Zhao, D. and J. S. Moore (2003). “Shape-persistent arylene ethynylene macrocycles: syntheses and supramolecular chemistry (a review).” Chem. Commun: 807-818 which is incorporated herein by reference. Such repetitive cyclooligomerization can result in concentric macrocycle structures.

The spokes can then be formed by reacting the hub precursor with a spoke precursor such that the spoke precursors are covalently attached around the hub to form the supramolecule. The spoke precursors can generally be reacted with the hub precursor. Although other reaction pathways can be used, the typical covalent linking reaction can include acid-base reaction between the dianhydride moiety of the perylene molecule (the spoke, as electron acceptor) and the primary amine moiety of the hub part (as electron donor).

Although other molecular functional groups can be used as the electron acceptor spokes, one specific example is perylene tetracarboxylic diimide (PTCDI) which forms an extremely robust class of materials with high thermal- and photo-stability, and strong absorption in the visible region making it an ideal light absorbing chromophore for solar cells. PTCDI has the structure

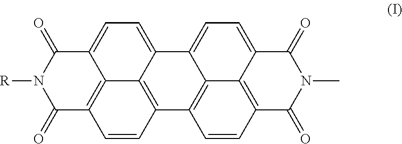

where R is an alkyl or polyalkoxy groups that provide the molecules with sufficient solubility for solution processing, while still maintaining effective cofacial stacking for the molecules. Other spoke groups can include the analogs of PTCDI that share the same high thermal- and photo-stability as PTCDI, as well as the electron accepting capability, but possess expanded conjugation (bay area). Typical examples include those with larger bay area that enhances the cofacial stacking, and thus the columnar growth of the film as depicted in FIG. 1. Non-limiting examples of such PTCDI analogs include

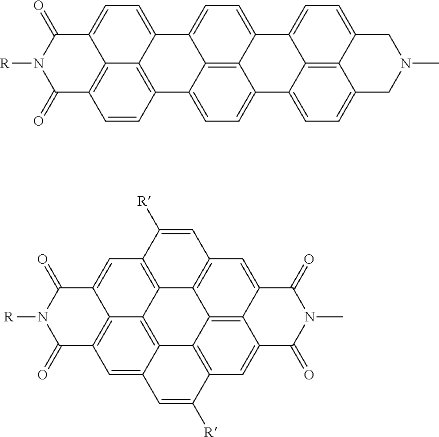

where R, and R′ are an alkyl or polyalkoxy groups that provide the molecules with sufficient solubility for solution processing, while still maintaining effective cofacial stacking for the molecules.

Generally, suitable spoke groups can be planar, enhance solubility for solution processing of the self-assembly to fabricate the columnar organized film as shown in FIG. 1, possess strong electron accepting capability, demonstrate high thermal-stability (against practical use of the solar cells in high temperature regions) and photo-stability (against photobleaching that may occur under long time strong sunshine illumination), and exhibit strong visible absorption enabling efficient utilization of sun light. It is also desirable that spoke and hub choices allow for π-π stacking of the supramolecules to form the stacks. Furthermore, the π-conjugated hub can have a different electron affinity than the electron acceptor spokes sufficient to provide an efficient intramolecular charge transfer upon photoexcitation.

In one specific aspect, the electron acceptor spokes are four PTCDI units covalently bonded to the π-conjugated hub. In one alternative, each of the electron acceptor spokes are formed of PTCDI covalently bonded to the π-conjugated hub via a phenylene bridge. A phenylene bridge is particularly suitable in that it is operable to mediate fast electron transfer between the π-conjugated hub and an electron acceptor spoke to enable efficient charge separation upon photoexcitation of the supramolecule.

As illustrations, the following section provides a number of specific and non-limiting example supramolecules using the above principles. In one aspect, the π-conjugated hub is formed of hexabenzocoronene (HBC) and each of the electron acceptor spokes are formed of perylene tetracarboxylic diimide (PTCDI) linked to the π-conjugated hub via a phenylene bridge such that the supramolecule has the structure

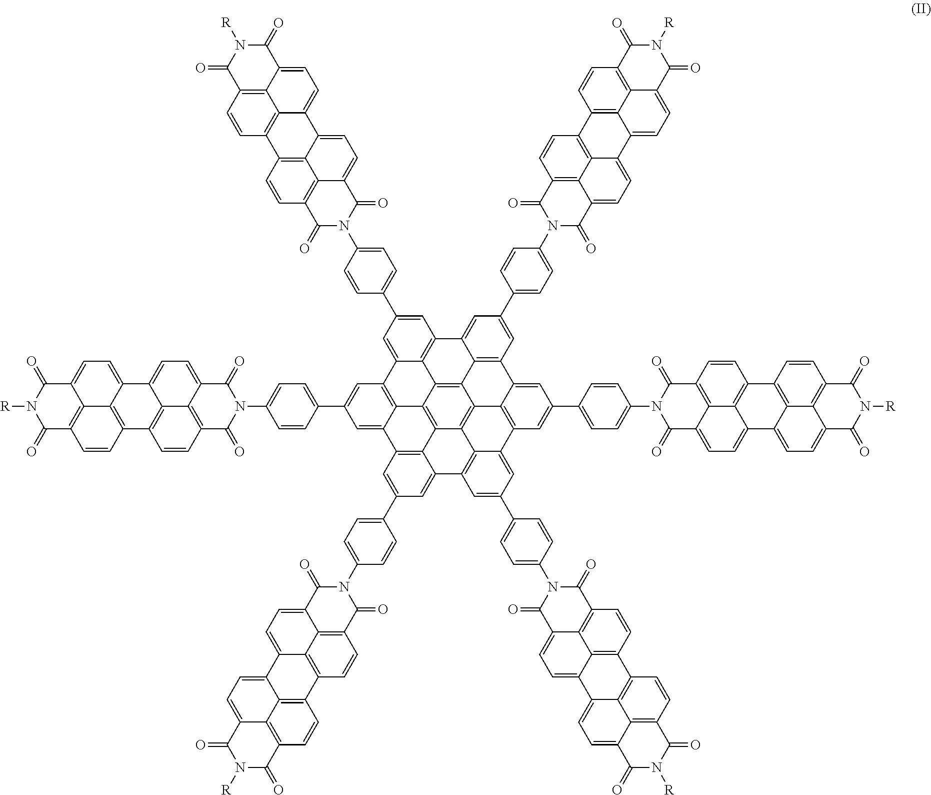

where R is an alkyl or polyalkoxy groups that provide the molecules with sufficient solubility for solution processing, while still maintaining effective cofacial stacking for the molecules.

In another aspect, the supramolecule can comprise PTCDI units as the spokes bonded to a carbazole tetracycle as the π-conjugated hub such that the supramolecule has the structure

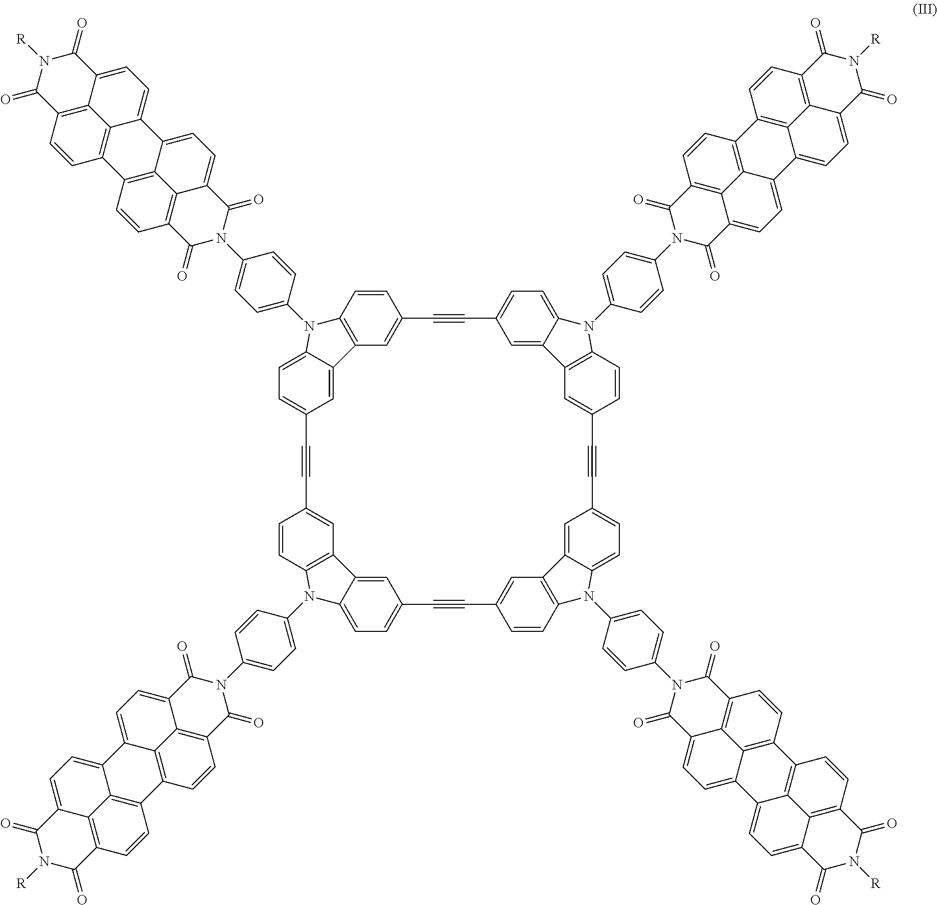

where R is an alkyl or polyalkoxy groups that provide the molecules with sufficient solubility for solution processing, while still maintaining effective cofacial stacking for the molecules. The phenylene linking groups in structures II and III illustrate that such groups can be useful in reinforcing coplanar geometry upon π-π stacking.

In yet another alternative, each supramolecule can comprise a PTCDI-AEM supramolecule having the structure

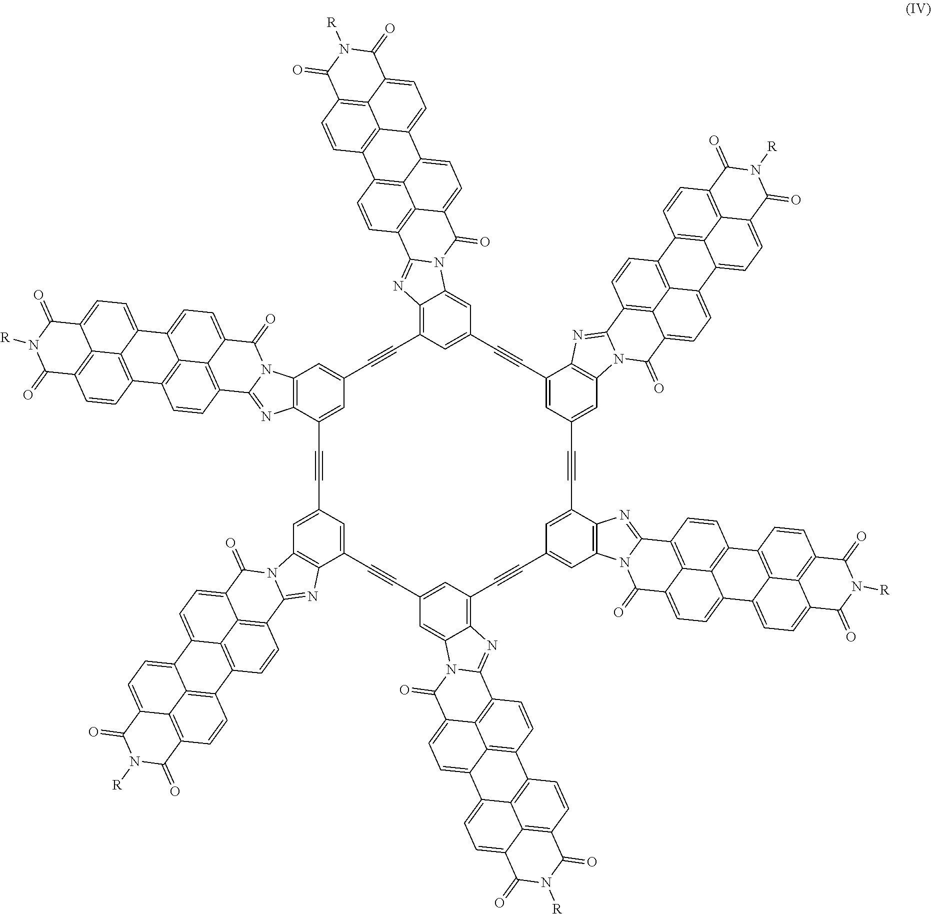

where R is an alkyl or polyalkoxy groups that provide the molecules with sufficient solubility for solution processing, while still maintaining effective cofacial stacking for the molecules. This supramolecule can be formed by first reacting the PTCDI (spoke precursor) with a phenyl diamine (as hub precursor segments) to form a spoke-hub segment as illustrated in FIG. 2. The segments can then be reacted to form the cyclic supramolecule.

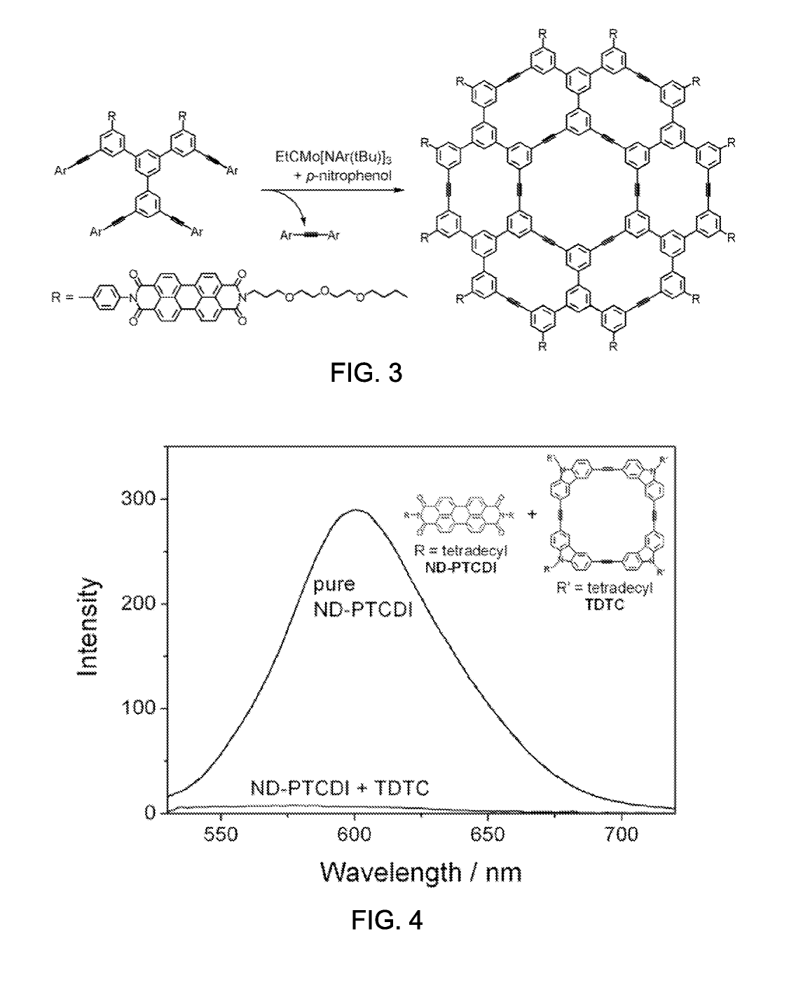

In still another aspect, each supramolecule is formed through repetitive cyclooligomerization of polyalkynyl precursors such that the supramolecule has the structure

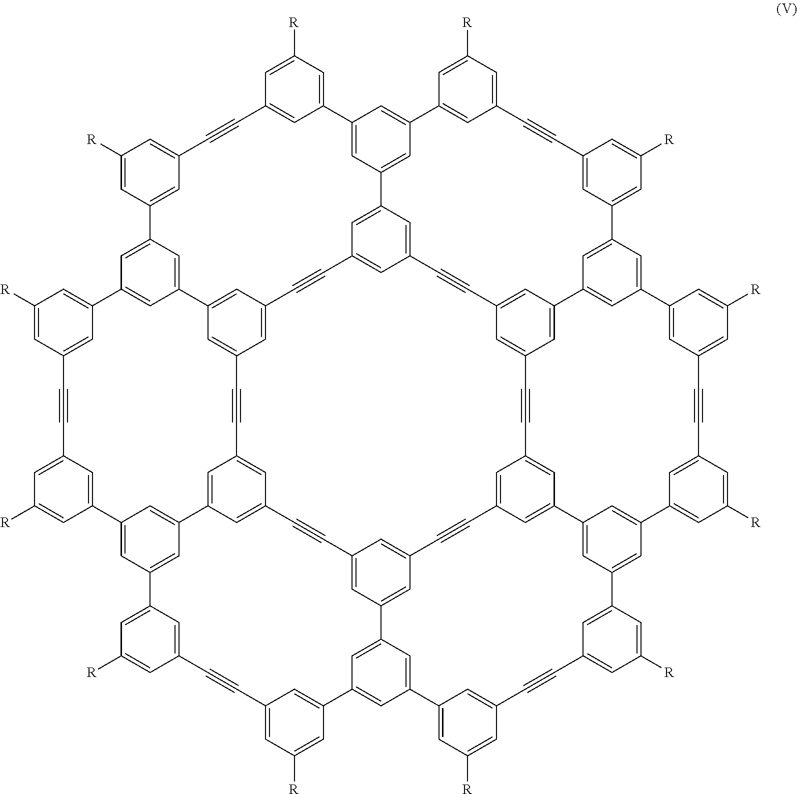

where R is the electron acceptor, specifically the PTCDI or expanded PTCDI as described above spokes. This structure V can be formed, for example, using polyalkynyl precursors as illustrated in FIG. 3. Each molecular stack can be formed of multiple macromolecules which are identical to one another to avoid stacking irregularities.

The first and second electrodes can be formed of any suitable conductive material. Further, these electrodes can be provided as a prepared plate or deposited, e.g. sputtering, vapor deposition, chemical deposition, atomic layer deposition, spin coating, or the like. Non-limiting examples of suitable conductive material can include metals, conductive ceramics, conductive polymers and the like. Especially for solar cells, at least one of the electrodes can be a substantially transparent or translucent material which allows light to pass through. Non-limiting examples of such material includes indium tin oxide (ITO) coated glass, aluminum doped zinc oxide films, transparent gold (e.g. ECI Inc.) coated glass, or extremely thin films. Transparent conductive oxides can also include fluorine doped tin oxide, and zinc tin oxide. Non-limiting examples of suitable conductive metal materials can include calcium, indium, aluminum, tin, silver, copper, gold, and combinations thereof. Conductive polymers can include, but are not limited to, poly(acetylene)s, poly(pyrrole)s, poly(thiophene)s, polyanilines, polythiophenes such as poly(3-alkylthiophenes), poly(p-phenylene sulfide), poly(para-phenylene vinylene)s, polyindole, polypyrene, polycarbazole, polyazulene, polyazepine, poly(fluorene)s, and polynaphthalene. The difference in work function of the two electrodes can be sufficient to enable electrons to migrate to one of the first and second electrodes. As a general guideline, a work function difference of at least 0.2 eV and in some cases up to about 1.0 eV or more can be suitable.

These organic semiconductor materials can be processed into large-area thin films and intelligently structured for highly efficient photocurrent production. As illustrated in FIG. 1, thin films of nanostructured coaxial columns are created via molecular engineering and supramolecular assembly. The coaxial column possesses both a large-area heterojunction interface to facilitate charge separation and a well-ordered, continuous conduit for efficient charge transport.

A method of forming a photovoltaic device having a coaxial molecular stack for transferring photocurrent can include coating a first electrode with a substantially continuous film formed of a plurality of coaxial molecular stacks. A second electrode can be coupled with the film such that a plane of the second electrode is substantially parallel with the plane of the first electrode. Distance between opposing electrodes can be kept substantially constant in order to prevent or reduce preferential shorting across the smallest gap distance. Although this distance can vary depending on the specific materials, the electrodes can often be separated a distance from about 10 nm to about 500 nm. Most often the distance can be about 50 nm to about 200 nm. For practical application as solar cell device, the film thickness can be controlled to be minimal to avoid charge carrier loss during the transport to the electrodes, but is still sufficient to absorb incident sun illumination. The first electrode can be coated with a substantially continuous film formed of the plurality of coaxial molecular stacks.

As mentioned previously, the π-conjugated hub can be formed of an arylene-ethynylene macrocycle (AEM) or other planar hub group and the electron acceptor spokes can be formed of perylene tetracarboxylic diimide (PTCDI) or other suitable spoke group. A homeotropic film can be formed by heating the continuous film above a selected temperature to form an isotropic phase in which the AEM molecules in the film are homogenously oriented. The film can then be cooled to room temperature at a rate sufficient to allow the isotropic phase to rearrange into a homeotropic phase to form a large area homeotropic phase in the continuous film. The coating of the first electrode with a homeotropic film formed can be accomplished via spin coating, physical vapor deposition, Langmuir-Blodgett membrane processes or the like.

Nanostructured thin films produced using the above principles are uniquely multifunctional, combining the properties of strong absorption of light waves in the visible wavelengths, efficient exciton dissociation, and efficient charge transport and collection. As the electron donor moiety is embedded directly into the electronic structure of the macrocycle, its unique cyclical π-conjugation facilitates efficient delocalization of the cationic charge, thereby stabilizing the photo-induced charge-separated state to minimize losses from electron-hole recombination.

Strong π-π stacking of the macrocyclic donors and their associated acceptor moieties along the columnar axis gives rise to efficient and concurrent transport of electrons and holes along the n-channel 22 and p-channel 20, respectively (FIG. 1). Due to the intrinsic difference in work function between the top and bottom electrodes, electrons and holes migrate toward opposite electrodes, leading to photocurrent production. Individual columns are separated by molecular insulation in the form of interdigitated alkyl side-chains, thereby preventing intercolumnar charge recombination or current leakage. Non-limiting examples of interdigitated alkyl side-chains include C5-C14 alkyls and polyalkoxy (e.g. polyethoxy, polypropoxy and the like).

Exciton diffusion, the usual bottleneck of efficiency for double-layered and even some bulk-heterojunction solar cells, is minimized by the exciton dissociation that occurs approximately at the site of photoexcitation. Consequently, coaxial nanostructured films can be sufficiently thick to absorb substantially all incident light, thereby leading to an increase in photoconversion efficiency. Combinations of these unique features can afford exceptional photovoltaic performance while still enjoying the ease of processing and fabrication available when using organic-based materials. The resulting organic photovoltaics provide significantly enhanced photoconversion that enables the organic material to be used in practical applications.

Fabrication of the coaxial column stack is based on disc-shaped macrocyclic molecules that spontaneously self-assemble into columnar arrangements driven by strong π-stacking interactions. Discrete macrocyclic molecular motifs can be prepared via efficient organic synthesis, yet they are highly engineered to possess multiple functions. The macrocycle's covalent architecture serves as a scaffold on which electron donor (D) and acceptor (A) moieties can be positioned so that the final assembled state produces spatial segregation among the donors and acceptors into a complementary pair of n- and p-channels, with minimal intermixing. The result of this nanoscale demixing is a large-area heterojunction interface throughout the material (i.e., a “bulk-heterojunction”).

The nanoscale Donor/Acceptor (D/A) demixing is approached through a “hub & spoke” architecture, in which a macrocyclic π-conjugated “hub” is covalently appended to multiple copies of an electron acceptor “spoke”. The “hub & spoke” design forms π-stacking arrangements that maximize intermolecular contact area that counterbalance the usual preference for D/A over A/A and D/D interactions. The “hub & spoke” design also promotes maximum molecular contact when donors are stacked against donors and acceptors against acceptors, giving rise to an internal p-channel surrounded by an outer n-channel, as shown in FIG. 1. The tunability of the macrocyclic chemistry enables a broad choice of a large number of structures from which a set of molecular design rules for the coaxial fabrication can be obtained. Moreover, PTCDI spokes forms an extremely robust class of molecules with high thermal- and photo-stability, and strong absorption in the visible light region that makes it an ideal light absorbing chromophore.

As a typical, but more organized bulk-heterojunction cell, the device illustrated in FIG. 1 uses efficient photoinduced charge transfer between the donor and acceptor components to afford high efficiency of light-to-electricity conversion. Such efficient charge transfer is supported by recent investigations of fluorescence quenching of PTCDIs and arylene ethynylene macrocycles (AEMs). When mixed at 1:1 molar ratio in a thin film, the fluorescence of a PTCDI molecule is almost 100% quenched by a tetracycle AEM, as illustrated in FIG. 4. The strong electron donating and accepting capability of AEM and PTCDI (respectively) is also illustrated by fluorescence quenching measurement using other quencher molecules, such as hydrazine or alkylamines for PTCDI, and nitrobenzene or nitrotoluene for AEM. Moreover, the charge separation state (the anionic radical) of PTCDI has been detected by electron spin resonance (ESR) measurement in both solutions and solid molecular assemblies.

Long-range π-electron delocalization along the molecular stacking has been proven by both the electron-spin resonance (ESR) measurements and the direct electrical conductivity measurements. The conductivity measured for a single PTCDI nanowire (composed of π-π stacking along the long axis) is about one order of magnitude higher than that measured from single polymer nanowires, e.g., one polythiophene, F8T2. The high conductivity observed is consistent with the organized one dimensional (1D) π-π stacking, which favors the conductivity through intermolecular π-delocalization. Efficient 1D charge transport enables fast charge collection at electrodes, while reducing the charge recombination between the anionic radical of the acceptor and the cationic radical of the donor within the coaxial column. Assuming that the individual coaxial columns are insulated from each other (i.e., no cross-column charge leaking), the efficient charge transport enabled by the π-π stacking makes the thin film fabricated from the coaxial column arrays an ideal photovoltaic module that can provide unprecedented photoconversion efficiency.

In addition to the highly organized π-π stacking, which is favorable for efficient charge separation and transport, the alignment of the coaxial columns perpendicular to the electrode surface, as shown in FIG. 1, is also favorable for the formation of efficient solar cells. The vertical alignment enables the most direct and shortest path for charge migration and maximal terminal contact of the coaxial column with the electrode, and thus enhances the charge collection at the electrodes.

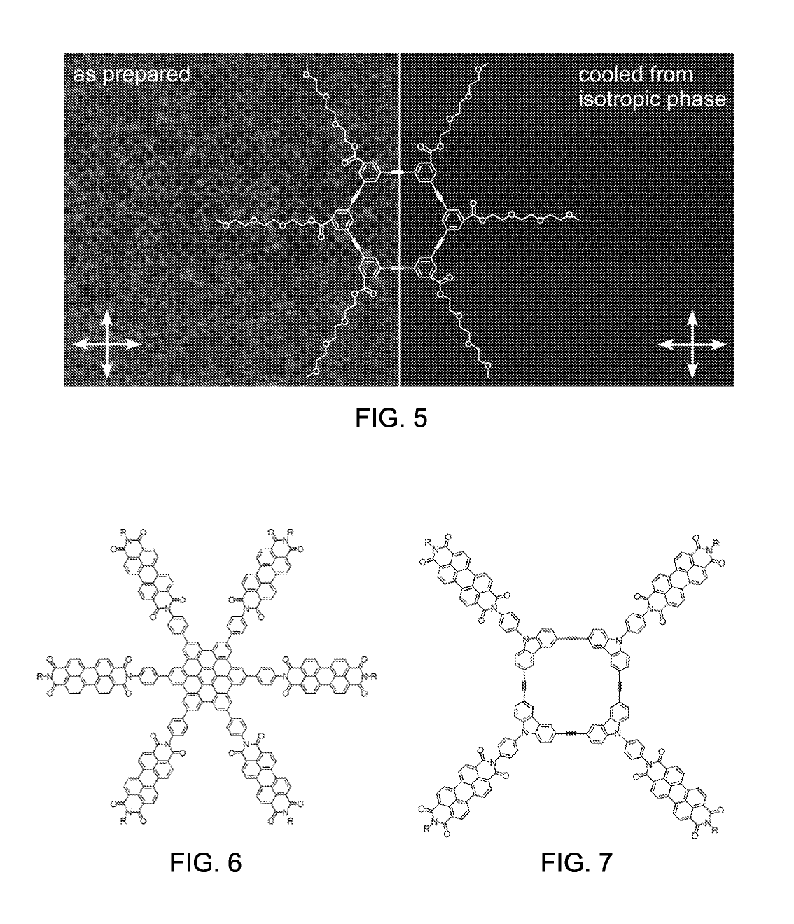

The fabrication of highly organized homeotropic films, in which the coaxial stacks are laterally arranged in a way with the long axis perpendicular to the electrode substrate, enables the efficient charge transport and collection. Such homeotropic films are highly suited for being sandwiched between two electrodes to fabricate efficient photovoltaic cells. The fabrication of thin films of a hexacycle AEM on glass is shown in FIG. 5.

The totally planar configuration of the homeotropic films, together with the oxygen-rich side-chains (which enhance the molecular interaction with hydrophilic surface like glass), enables effective π-π stacking to form a homeotropic phase as typically observed for discotic liquid crystal molecules. Although the freshly drop-cast film may contain randomly orientated columnar stacking (FIG. 5 left), thermal annealing of the film leads to formation of a large area homeotropic phase, as evidenced by the dark image (no birefringence) obtained under a cross-polarized microscopy imaging (FIG. 5 right). This demonstrates an easy way to fabricate homeotropic film using a structurally optimized molecule. The fabrication of such a homeotropic fabrication onto an indium-tin-oxide (ITO) coated substrate is discussed below in more detail. The use of the ITO substrate enables the homeotropic film and substrate to be employed as the transparent electrode of a solar cell.

### EXAMPLES

### Synthesis of Various π-Conjugated Macrocycles Suitably Functionalized with Redox-Active Groups, and Programmed Via π-Stacking Interactions that Will Favor 1D Columnar Self-Assembly

Efficient Charge Separation Mediated by Phenylene Bridge.

Blend films comprising PTCDI and hexabenzocoronene (HBC) demonstrate high performance in photovoltaic devices, where the segregated phase of the two molecular aggregates facilitates the charge transport. A star-like supramolecule consisting of an HBC center surrounded by four PTCDI units, as shown in FIG. 6, can be synthesized. The two parts are linked with a phenylene bridge, which is twisted at about 40 degrees with respect to the PTCDI and HBC planes, thereby enforcing a co-planar configuration of the whole molecule. The planar configuration is conducive to the strong π-π stacking with minimal offset. A phenylene bridge is also used to mediate fast electron transfer, thus enabling efficient charge separation upon photoexcitation. This is in contrast to the film blend simply mixed with D and A molecules, for which the short exciton diffusion is often the bottleneck for the photoinduced electron transfer between the segregated D and A phase, thus limiting the photoconversion efficiency.

Another star-like molecule that can be synthesized is shown in FIG. 7, which incorporates PTCDI units onto a carbazole tetracycle. Research has shown a close to 100% emission quenching of PTCDI by the same tetracycle in an equally mixed film, thereby evidencing an efficient photoinduced charge transfer between the two segments. The cationic state thus generated at the central core is stabilized due to the high delocalization around the conjugated cycle. The electron located on the PTCDI also gains stability when the molecules are stacked into a highly organized crystalline phase, since the electron can be a delocalized intermolecular along the π-stacking direction.

The star-like molecule is also in a co-planar configuration as coincident with the twisted phenylene bridge. The homeotropic film favors co-facial stacking. The twisted phenylene bridge may cause helical offset for the π-π stacking, resulting in tight spatial filling along the stacking column. Such a bulky molecular arrangement can provide tightly packed films, leaving substantially no or no spatial defects inside the film. Indeed, rotational offset along the stacking axis (as demanded for energy minimization) was observed for discotic molecules such as hexabenzocoronene.

Charge Separation Via HOMO-LUMO Electronic Redistribution.

As shown in FIG. 2, a PTCDI substituted hexacycle is used as the self-assembling building block for manufacturing a coaxial column structure. The totally planar molecule can stack strongly due to the large area of molecular contact, thereby leading to the formation of a highly organized homeotropic phase, as observed for large discotic molecules. Solubility can be problematic, but can be rectified by appropriate side-chain modification. The modular construction of the precursor monomer lends itself to rapid iteration, in order to identify structures which overcome solubility limitations.

One advantage of employing such a supramolecular structure in solar cell materials is the extended absorption spectra of PTCDI (which includes the entire visible region of light) caused by conjugation with a Schiff base. In combination with the absorption of solid state AEM (up to ˜400 nm), the film made of this PTCDI-AEM supramolecule provides broad spectral sensitivity, and increased utilization of solar energy. Moreover, due to the different electron affinity (reduction-oxidization capability) of PTCDI and AEM, the supramolecule can enable a coherently efficient intramolecular charge transfer upon photoexcitation. Such a charge transfer is favored by the conjugate structure in FIG. 2 (Structure IV).

The electronic redistribution between the highest occupied molecular orbital (HOMO) and the lowest unoccupied molecular orbital (LUMO) shows a pronounced intramolecular charge separation upon photoexcitation. Although charge separation can be sufficient to be functional, a charge separation of above about 95%, and in one aspect about 100% can be particularly desired. Considering the rigid, planar conformation of the molecule, a similar molecular orbital geometry can be maintained when stacked into a columnar phase in the film, and thereby the efficient photoinduced charge separation will enhance the generation of charge carriers. This molecule is highly complementary to the phenylene-linked molecules shown in FIG. 6 and FIG. 7 in terms of optoelectronic optimization and the subsequent evaluation of the films in solar cell application, particularly in exploring the molecular structure effect on charge generation and separation.

Concentric Macrocycles for Increased π-Surface

The strength of π-π stacking is strongly dependent on the area of molecular contact between aromatic systems. Large π-surfaces also help tolerate the possible twisting configuration of the rim segments (e.g., the PTCDI or spoke moiety) with respect to the central plane, thus helping maintain the effective π-π stacking. Moreover, the increased π-system also enhances the π-delocalization that helps stabilize the intramolecular charge separation, eventually leading to increased photoconversion efficiency. AEMs can be synthesized with controllable size and shape by approaches that involve double strand formation.

For example, FIG. 3 shows how concentric macrocycles can be prepared by cyclooligomerization. The π-stacking between these large-size shape-persistent objects are dramatically enhanced compared to the smaller monocycles. The molecular structures can be subjected to modification, including the introduction of redox active units to make fully π-delocalized nanopatches that are highly desired for charge separation and transport.

### Fabrication and Characterization of Homeotropic Thin Films Consisting of Large-Area Arrays of Coaxial Columns.

Fabrication of Thin Films Via Spin-Coating.

The fabrication of an organized film having a relatively large area on a bottom electrode of a solar cell can substantially enhance the performance of the solar cell, as previously discussed. In one embodiment, the film on the bottom electrode can be formed using ITO coated glass. Glass substrates are relatively inexpensive and can be cleaned using wet chemical methods. A glass surface cleaned by a piranha reagent (30:70 H₂O₂(35%):H₂SO₄) shows a roughness of only about 0.8 nm, which is much smaller than the dimensional size of the molecules. Such a flat surface is suitable for both the surface fabrication and microscopy characterization. An ITO coated surface is more hydrophobic than glass, and thus is more favorable for face-on adsorption for planar aromatic molecules due to enhanced hydrophobic interaction between molecules and the ITO surface. Moreover, the surface polarity of ITO can be adjusted (i.e. increased or decreased) over a wide range by argon or oxygen plasma treatment to accommodate the effective adsorption of the molecules that may have various polarity preferences due to the different core and side-chain structures, as previously discussed.

Spin-coating can be employed to fabricate the nanostructured thin films having uniform thickness. Due to the fast evaporation, films made by spin-coating usually possess crystalline defects caused by distorted orientation of columnar stacks or large offset of π-π stacking. To remove these defects, the film can be treated by thermal annealing via heating-cooling cycles. This facilitates molecular reorganization in the film, thereby leading to the formation of a relatively large-area of the film having a homeotropic phase, as shown in FIG. 5 in the as-prepared state (left) and annealed state (right).

Thermal annealing takes advantage of the low melting point of liquid crystal property of the molecules with long side-chains. Another approach to structural optimization of film is based on solvent vapor treatment for in situ fabrication of 1D nanostructures on polar substrates. This approach can be performed in a closed chamber saturated with an appropriate solvent vapor, e.g. chloroform, dichloromethane, hexane, methanol and/or ethanol. Depending on the molecular structure and solubility, solvents of different polarity or a combination of solvents can be used in order to induce the molecular reorganization.

Fabrication of Thin Films Via Vacuum Vapor Deposition.

In addition to the wet-chemical methods described above, a physical vapor deposition (PVD) technique can also be employed to fabricate an organized thin film using layer-by-layer deposition. A high vacuum PVD chamber can be used. The deposition speed can be feasibly controlled by adjusting the chamber temperature and initial vacuum (or molecular vapor pressure). One factor controlling the deposition speed is the strength of the intermolecular interaction. In case such interaction is weak or the π-π stacking is not sufficiently superior over the lateral molecular association, the deposition speed should be carefully controlled to allow sufficient time for molecules to assemble into the desired homeotropic organization.

Large-area organized monolayer of both AEM and PTCDI molecules have been successfully fabricated by PVD methods. The lateral organization is largely controlled by the 2D interdigitation between side chains due to hydrophobic interactions. Using these highly organized monolayer network as crystal-growth seeds, uniform homeotropic phase can be fabricated using layer-by-layer growth of the columnar stacking, for which the freshly deposited molecules will prefer stacking with maximal overlapping with the previously deposited molecule, leading to columnar growth perpendicular to the substrate. By adjusting the deposition rate and time, the thickness of film can be precisely controlled.

Electronic Calculations for Molecular Design.

The molecular design rule for the coaxial nanostructured materials for the photovoltaic application lies in three folds: efficient intramolecular charge separation upon photoexcitation, effective cofacial stacking to afford intermolecular charge migration, and sufficient lateral association between the stacking columns to enforce formation of large-area array with minimal spatial defects.

To achieve a suitable set of molecular design calls for close coordination between experimental practice (including synthesis and spectral measurements) and theoretical studies of molecular electronic structures. In particular, estimation of spatial charge separation between the D and A units can be based on the calculation of the relevant molecular orbitals such as the LUMO and HOMO orbitals. The electronic structure of a given candidate D-A supramolecule is calculated from its energy-minimized structure using first-principles methods.

Intracolumn Molecular Interaction and Stacking—a Coarse-Graining Approach.

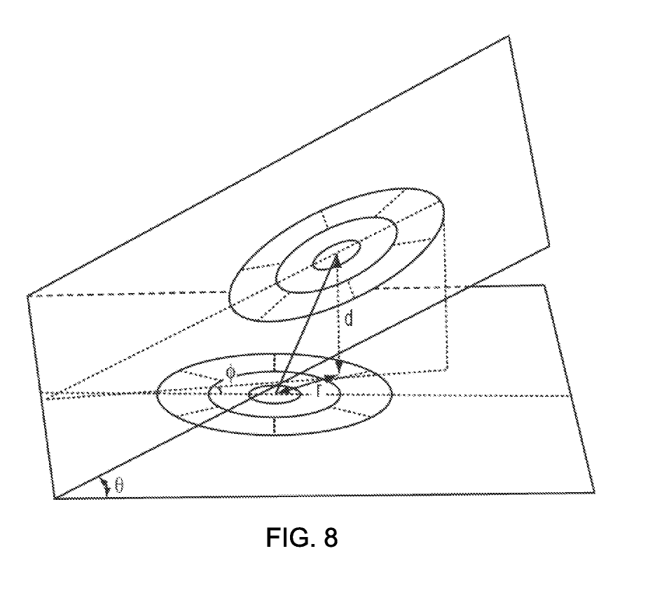

The columnar stacking of the disc-shaped macrocyclic molecules is governed by cofacial intermolecular interactions. A generic model can be used to describe such interactions using a coarse-graining approach, as illustrated in FIG. 8. A macrocyclic molecule is “homogenized” into a multi-ring axisymmetric disc, and the columnar disc-disc interaction is characterized by four basic parameters: the vertical separation, d; the concentric displacement, r, the azimuthal angle, φ, and the inclination angle, θ. First, extensive first-principles calculations are used to map out the interaction energies between two molecules in the parameter space of (d, r, φ, θ). Then, the first-principles potential-energy surface V(d, r, φ, θ) is fit with a chosen empirical force-field to account for the π-stacking interaction.

Given V(d, r, φ, θ), using a variational method, mathematical modeling can be performed for the structure of a single column consisting of a stack of discs by minimizing the energy of collective disc-disc interactions as a function of disc displacements and orientations. Of particular interest is the disc-defect formation energies (caused by a disc displacement or disorientation) and possible disordering mechanism. The results of a whole column can then be homogenized into a cylinder with an averaged potential, which is to be used in the study of intercolumn interaction for lateral assembly into a film. The intercolumnar interaction can be estimated with certain simplification at the molecular level, for which the intermolecular association is dominated by the hydrophobic interdigitation between the alkyl side-chains.

In accordance with one embodiment, a solar cell can be fabricated as a conventional sandwich-like device, in which the active semiconductor film can be packed between two planar electrodes. The top metal electrode (e.g. aluminum) can be deposited using sputter coating. Slow metal deposition produces interpenetration between the electrode and film, resulting in effective electrical contact. Such interpenetration is limited within the top layers of the film mainly due to the cross-film space-filling caused by the rotated and offset stacking of molecules. Thus no short circuit or other electrical leaking problem is expected. The active area of the cell can be controlled and adjusted by coating different sizes of the top electrode through a shadow mask. Typically, an active area of ˜10 mm² can be effective. Current-voltage (I-V) measurement can be performed in the dark for the fabricated cell and be compared with the typical value expected for the π-stacked materials, which can be measured with single nanowires. Such I-V calibration helps to ensure good device quality by excluding electrical leaking or a short circuit that may be caused by defects in the film. Correlating the measured film conductivity with the phase structure (columnar stacking and arrangement) also provides improved understanding of the structural dependence of charge transport.

Photocurrent can be measured as a function of applied voltage under monochromic irradiation at a specific wavelength. This, compared to the dark I-V curve described above, enables the photosensitivity of the fabricated materials to be estimated, an important parameter typically used for evaluating solar cell materials. From the photocurrent-voltage plot, several other important parameters that affect solar cell performance can also be deduced, including short-circuit current (I_{SC}), open-circuit voltage (V_{OC}), fill factor (FF) and incident photon conversion efficiency (IPCE) at a single wavelength. These parameters can be compared to the values reported for other organic based solar cells, such as those fabricated from conducting polymers and C60, which have so far represented one of the most efficient organic materials for photovoltaic devices. Specific attention is paid to the fill factor, which is usually in low value for single-layer cells, mainly due to the large series of resistance associated with the insulating nature of the organic layer and thus the field-dependent generation of charge carriers. A high fill factor value can be obtained for devices using the film described above. Devices using the film can be considered as a special class of bulk-heterojunction cells with highly organized homeotropic materials for efficient charge transport. In these devices, the charge generation is primarily a photodriven process, and thus will have low field-dependency.

In general, there is a tradeoff between film thickness and photoconversion efficiency for a cell. On one hand, the thicker the film, the more light will be absorbed; on the other hand, an increased thickness may increase the probability of charge recombination due to the longer path of charge transport. The optimization of cell performance is also based on the selection of top metal electrodes. By using different metals, a wide range of work-functions (Fermi levels) for the electrode are provided, which may produce different open-circuit voltage for the cell. As previously observed for bulk-heterojunction cells, V_{OC} of the coaxial column cell is dependent on the work-function difference (ΔE_{F}) between the two electrodes, with slight dependence on the LUMO (and HOMO) level of the acceptor (and donor). Seven metals with dramatically different work-functions can be particularly exploited as the top electrode, calcium (Ca, work function 2.9 eV), indium (In, 4.1 eV), aluminum (Al, 4.3 eV), tin (Sn, 4.4 eV), silver (Ag, 4.7 eV), copper (Cu, 4.9 eV), and gold (Au, 5.3 eV). In addition to V_{OC}, I_{SC} and IPCE can also be correlated with the different metal electrodes.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

1. A photovoltaic device having a coaxial molecular stack for transferring photocurrent, comprising:
a plurality of coaxial molecular stacks located between and oriented substantially perpendicular to a first electrode and a second electrode to provide charge transport of photocurrent through each coaxial molecular stack in the photovoltaic device, wherein each coaxial molecular stack comprises:
a plurality of π-conjugated planar supramolecules stacked through columnar self assembly to form the coaxial molecular stack, wherein each supramolecule is comprised of a π-conjugated hub covalently appended to multiple copies of an electron acceptor spoke to form an outer n-channel with a coaxial inner p-channel.

2. The photovoltaic device of claim 1, wherein the π-conjugated hub is formed of at least one of arylene ethynylene macrocycle (AEM), hexabenzocoronene (HBC), porphyrins, thiophene macrocycles, and toroidal graphenes.

3. The photovoltaic device of claim 1, wherein the π-conjugated hub is formed of hexabenzocoronene (HBC) and each of the electron acceptor spokes are formed of perylene tetracarboxylic diimide (PTCDI) linked to the π-conjugated hub via a phenylene bridge such that the supramolecule has the structure 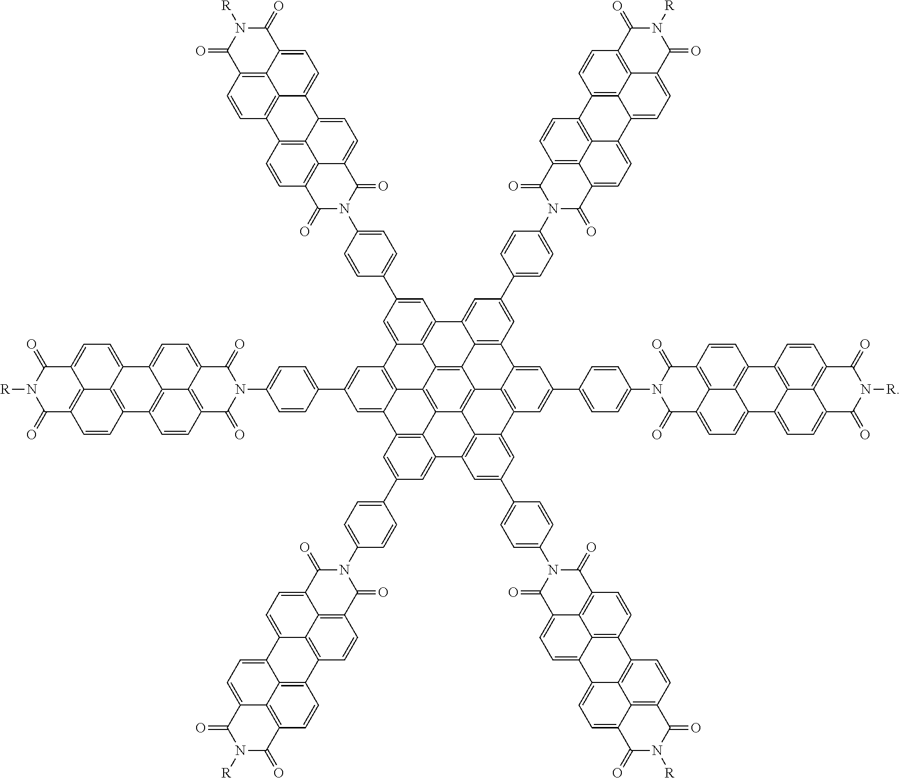
where R is an alkyl or polyalkoxy group.

4. The photovoltaic device of claim 1, wherein each supramolecule comprises PTCDI units as the spokes bonded to a carbazole tetracycle as the π-conjugated hub such that the supramolecule has the structure 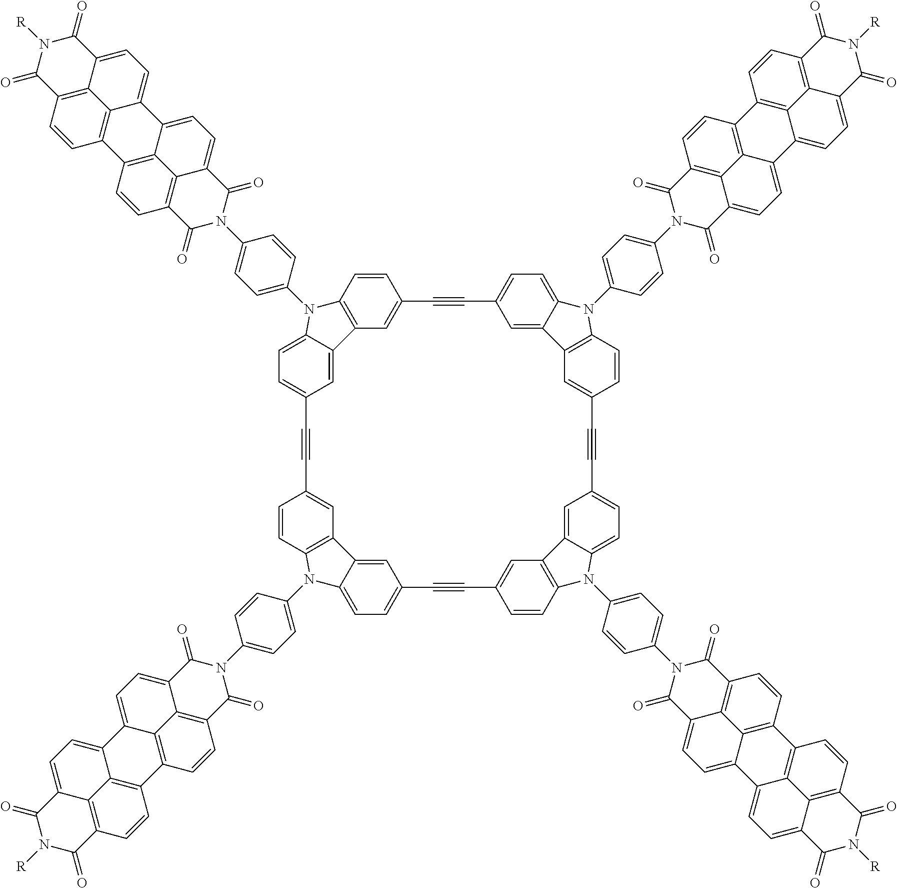
where R is an alkyl or polyalkoxy group.

5. The photovoltaic device of claim 2, wherein each supramolecule comprises a PTCDI-AEM supramolecule having the structure 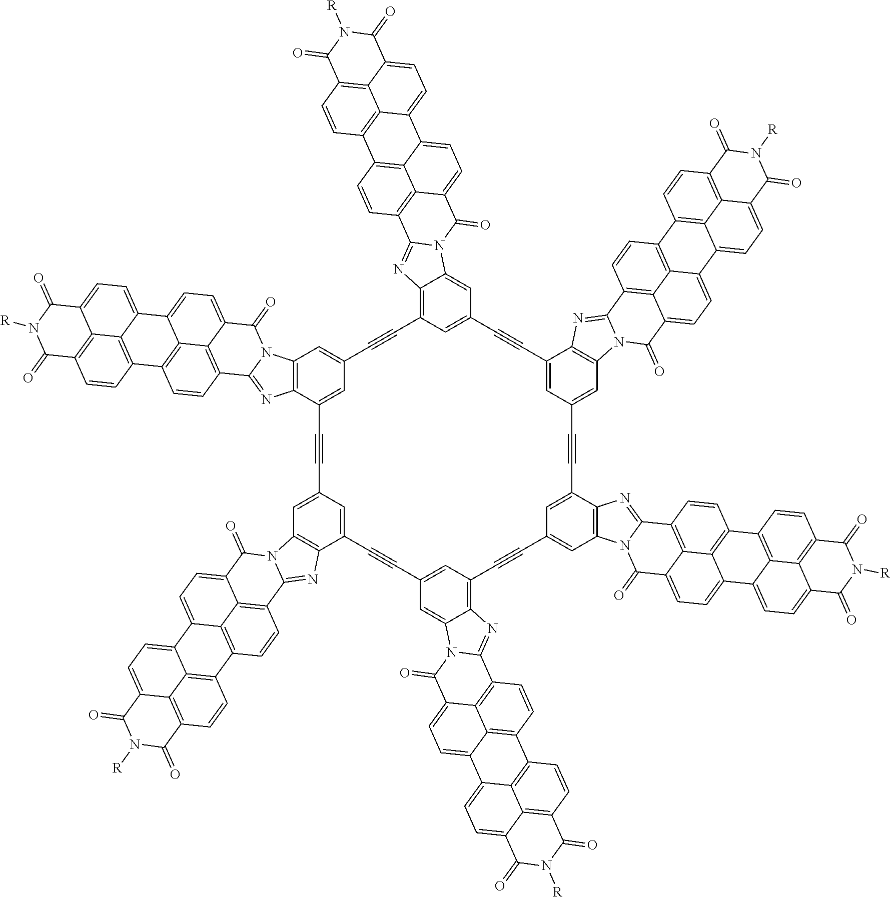
where R is an alkyl or polyalkoxy group.

6. The photovoltaic device of claim 1, wherein each supramolecule is formed through repetitive cyclooligomerization of polyalkynyl precursors such that the supramolecule has the structure 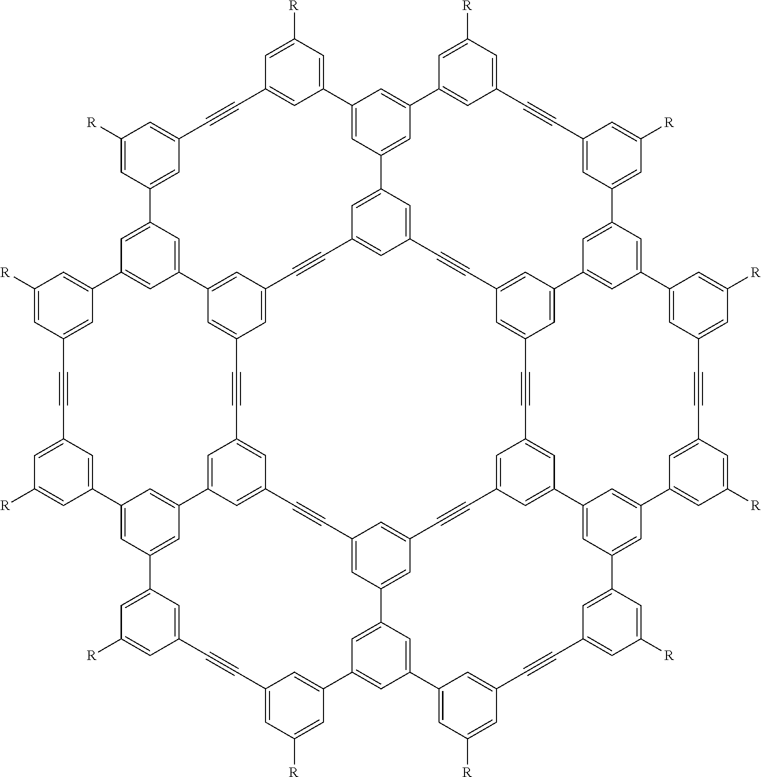
where R is the electron acceptor spoke.

7. The photovoltaic device of claim 1, wherein the electron acceptor spokes are a perylene tetracarboxylic diimide or analog thereof.

8. The photovoltaic device of claim 7, wherein each of the electron acceptor spokes is a perylene tetracarboxylic diimide having the structure 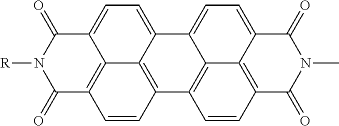
where R is an alkyl or polyalkoxy group.

9. The photovoltaic device of claim 1, wherein at least one of the first and second electrodes is an indium tin oxide (ITO) coated glass.

10. The photovoltaic device of claim 1, wherein at least one of the first and second electrodes is formed from a material selected from the group consisting of calcium, indium, aluminum, tin, silver, copper, gold, and combinations thereof.

11. The photovoltaic device of claim 1, wherein the electrodes are separated a distance of about 10 nm to about 500 nm such that the plurality of coaxial molecular stacks span the distance.

12. A method of forming a photovoltaic device having a coaxial molecular stack for transferring photocurrent, comprising:
coating a first electrode with a substantially continuous film formed of a plurality of coaxial molecular stacks, wherein each coaxial molecular stack is formed of a plurality of stacked supramolecules, and each supramolecule is comprised of a π-conjugated hub covalently appended to multiple copies of an electron acceptor spoke to form an outer n-channel with a coaxial inner p-channel substantially perpendicular with a plane of the first electrode; and
coupling a second electrode with the film, wherein a plane of the second electrode is substantially parallel with the plane of the first electrode.

13. The method of claim 12, wherein coating further comprises coating the first electrode with a substantially continuous film formed of the plurality of coaxial molecular stacks.

14. The method of claim 12, wherein coating further comprises:
forming a homeotropic film by heating the continuous film above a selected temperature to form an isotropic phase in which the AEM molecules in the film are homogenously oriented; and
cooling the film to room temperature at a rate sufficient to allow the isotropic phase to rearrange into a homeotropic phase to form a large area homeotropic phase in the continuous film.

15. The method of claim 12, wherein coating the first electrode further comprises coating the first electrode with a homeotropic film formed via spin coating.

16. The method of claim 12, wherein coating the first electrode further comprises coating the first electrode via physical vapor deposition on at least one of the first and second electrodes.

17. The method of claim 12, wherein the π-conjugated hub is formed of at least one of arylene ethynylene macrocycle (AEM), hexabenzocoronene (HBC), porphyrins, thiophene macrocycles, and toroidal graphenes.

18. The method of claim 13, wherein the electron acceptor spokes are a perylene tetracarboxylic diimide or analog thereof.

19. The method of claim 13, wherein the second electrode is coupled via at least one of sputtering, vapor deposition, chemical deposition, atomic layer deposition, and spin coating.

20. A π-conjugated planar supramolecule comprising a π-conjugated hub having multiple electron acceptor spokes covalently appended to the hub, said hub having one of the following structures where R is the electron acceptor spoke: 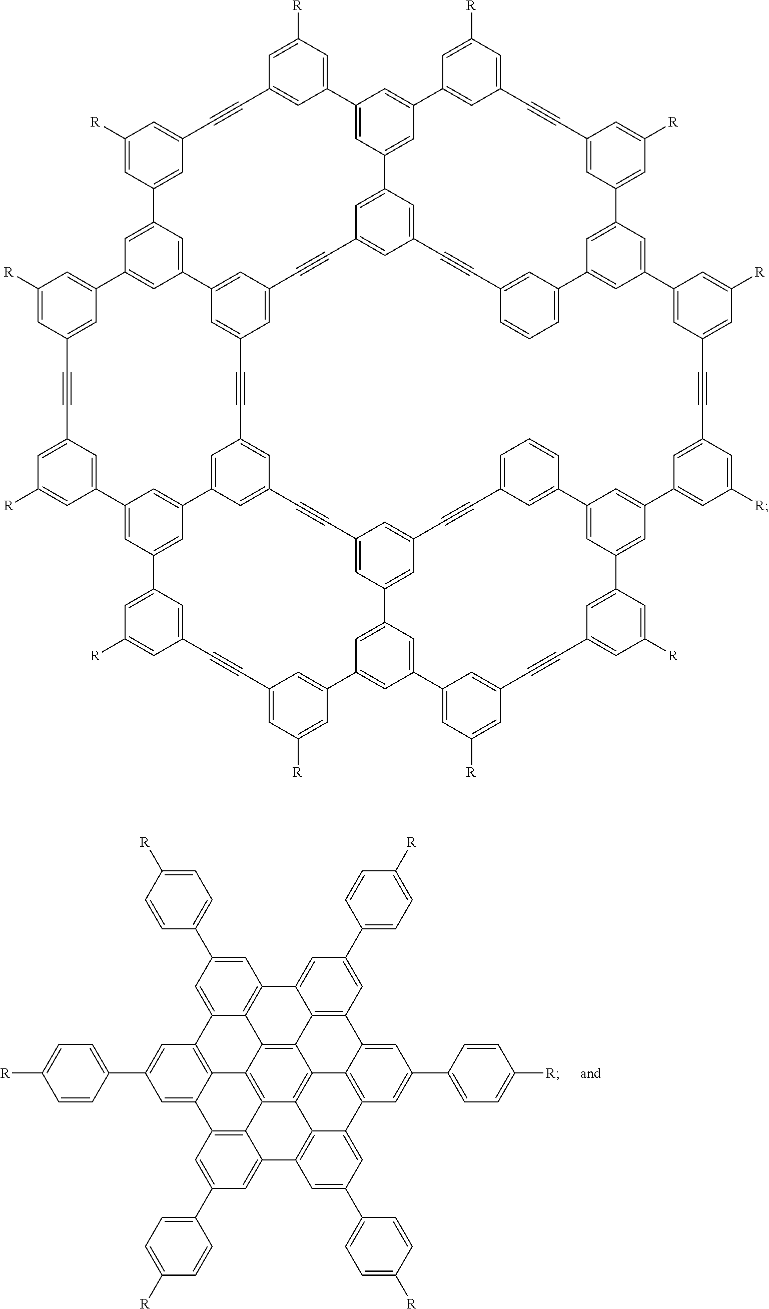 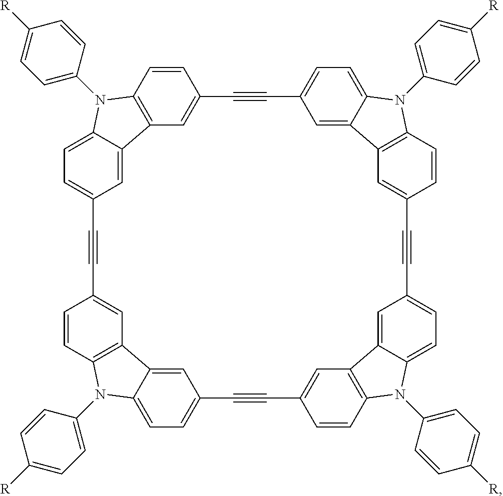
where R is one of: 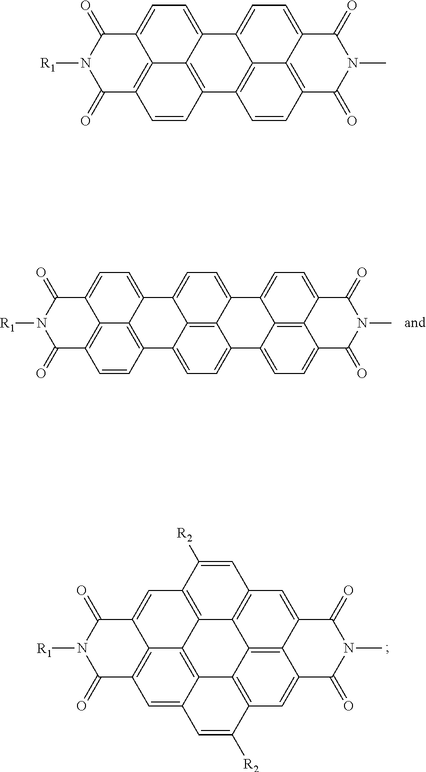
or the π-conjugated planar supramolecule has the formula 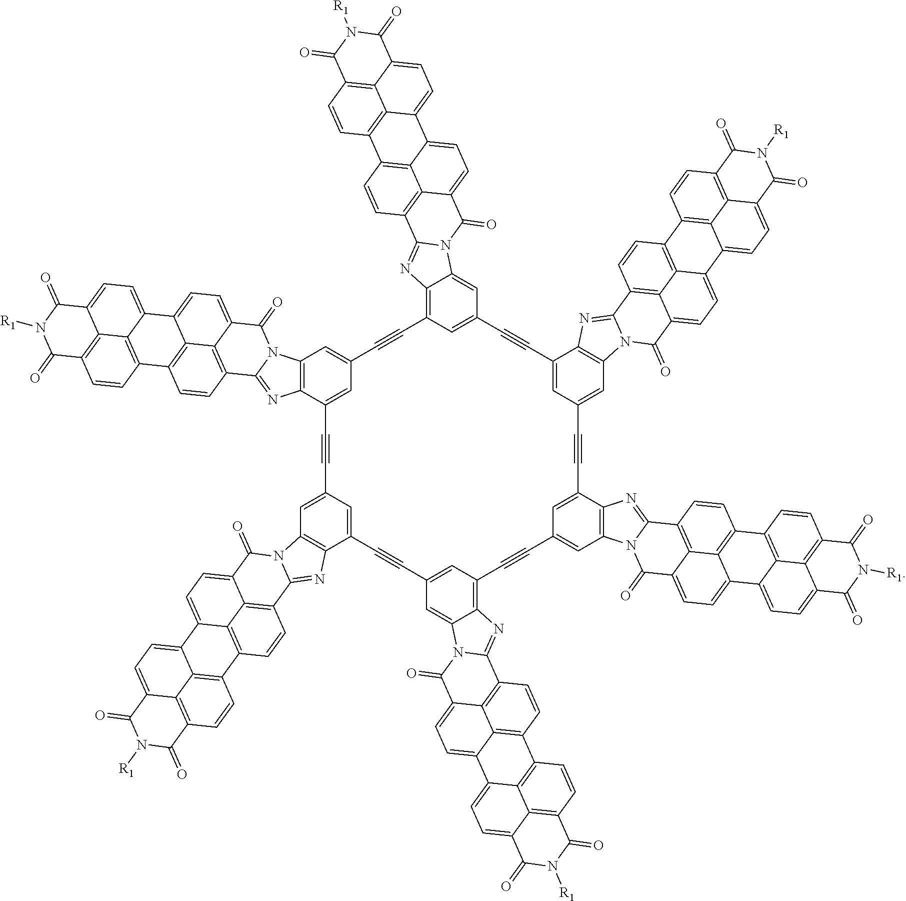
where R1 and R2 are an alkyl or polyalkoxy group.
